(19) United States
(12) Patent Application Publication
(10) Pub. No.: US 2011/0068469 A1
(43) Pub. Date: Mar. 24, 2011

(54) SEMICONDUCTOR PACKAGE WITH PRE-FORMED BALL BONDS

(75) Inventors: Kai Yun Yow, Petaling Jaya (MY); Poh Leng Eu, Petaling Jaya (MY)

(73) Assignee: FREESCALE SEMICONDUCTOR, INC, Austin, TX (US)

(21) Appl. No.: 12/957,419

(22) Filed: Dec. 1, 2010

Related U.S. Application Data
(62) Division of application No. 12/204,810, filed on Sep. 5, 2008.

(51) Int. Cl. H01L 23/498

(52) U.S. Cl. 257/738; 257/E23.069

(57) ABSTRACT

A semiconductor package includes an integrated circuit die having first and second sets of connection pads, bond wires, and a substrate with connection pads. The bond wires electrically connect the second set of connection pads of the die with the substrate connection pads. Prior to connecting the wires to the second connection pads, a free air ball (FAB) is formed and pressed against a respective one of the connection pads of the first set to form a pre-formed ball bond.

### CROSS-REFERENCE TO RELATED APPLICATIONS

This application is a divisional application of U.S. application Ser. No. 12/204,810 filed on Sep. 5, 2008.

### BACKGROUND OF THE INVENTION

The present invention relates to wire bonding and more particularly to a method of forming a ball bond.

Ball bonding is widely employed in the semiconductor packaging industry to form electrical connections between an integrated circuit (IC) die and a die carrier such as a lead frame or a substrate.

Conventional ball bonding processes typically use a combination of heat, pressure and ultrasonic energy to form an intermetallic connection or weld between a wire and a connection pad. However, as the connection pad is typically subjected to a number of stressors such as impact force, contact power, contact force, bond power and bond force during the ball bonding process, the connection pad consequently is susceptible to cracking. Reliability becomes an issue when a crack extends into underlying metallization and silicone oxide structures. Thus, a need exists for a ball bonding method that reduces the number of stressors on a bonding site during ball bonding.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view illustrating a step of bringing a bonding ball towards a first surface in accordance with an embodiment of the present invention;

FIG. 2 is an enlarged cross-sectional view illustrating a preformed bonding ball in accordance with an embodiment of the present invention;

FIG. 3 is an enlarged cross-sectional view illustrating a ball bond in accordance with an embodiment of the present invention;

FIG. 4 is an enlarged cross-sectional view illustrating a preformed bonding ball in accordance with another embodiment of the present invention; and

FIG. 5 is an enlarged partial top plan view of a semiconductor package in accordance with one embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of forming a ball bond including the step of forming a bonding ball at an end of a bonding wire. The bonding ball is preformed to a substantially ball bond shape at a preform location remote from a bonding site. The preformed bonding ball is subsequently bonded to the bonding site.

The present invention also provides a method of forming a ball bond including the step of forming a bonding ball at an end of a bonding wire. The bonding ball is deformed against a first surface. The deformed bonding ball is subsequently removed from the first surface and bonded to a second surface.

The present invention further provides a semiconductor package including a die carrier having a plurality of bonding sites. An integrated circuit (IC) die is attached to the die carrier, the IC die having a plurality of first connection pads and a plurality of second connection pads. Indentation marks are formed on the first connection pads. A plurality of wire bonds electrically connects the bonding sites on the die carrier to the second connection pads on the IC die.

A method of forming a ball bond 10 will now be described below with reference to FIGS. 1 through 3. The ball bonding process described below may be performed using currently available wire bonders such as, for example, an ASM Eagle 60-Series wire bonder, an ASM Twin Eagle wire bonder, a K&S Maxum Ultra wire bonder, a K&S Maxum Elite wire bonder and a K&S Model 8090 wire bonder.

Referring now to FIG. 1, a step of bringing a bonding ball 12 towards a first surface 14 is shown. The bonding ball 12 is formed at an end of a bonding wire 16 near the tip of a capillary bonding tool 18. As indicated by the arrow in FIG. 1, the bonding ball 12 is moved downwards by the capillary bonding tool 18 to contact the first surface 14. In the embodiment shown, the first surface 14 is a surface of a preform plate 20. The preform plate 20 is remote from a bonding site, as is described below. In one embodiment, the preform plate 20 may be adjacent the bonding site.

The bonding ball 12 may be a free air ball (FAB) formed in a known manner, for example, by applying a high voltage electric charge to the bonding wire 16 to melt the bonding wire 16 at the tip of the capillary bonding tool 18. Accordingly, further description of the formation of the bonding ball 12 is not required for a complete understanding of the present invention. The bonding ball 12 may have a diameter of between about 45 microns (μm) and about 65 μm. It should however be understood that the present invention is not limited by the diameter of the bonding ball 12. The bonding ball 12 may have a larger or smaller diameter depending on, for example, the type of bonding wire 16 used and the method by which the bonding ball 12 is formed.

The bonding wire 16 may be made of gold (Au), copper (Cu), aluminum (Al) or other electrically conductive materials as are known in the art and commercially available and may have a diameter of between about 15 μm and about 60 μm, although wires of other diameters may also be used and the invention should not be limited to a particular wire diameter. As is known by those of skill in the art, various size wires are available for ball bonding, with the wire size being selected based on, among other things, the spacing between bonding sites.

The capillary bonding tool 18 may be made from ceramic, tungsten or ruby materials, as are typically used. Such a bonding tool is well known in the art and therefore, further description of the capillary bonding tool 18 is not required for a complete understanding of the present invention.

In the present embodiment, the preform plate 20, and thus also the first surface 14 against which the bonding ball 12 is subsequently contacted, is made of a harder material than the bonding wire 16. For instance, if copper (Cu) bonding wire 16 is used, the preform plate 20 may be made of ceramic with a mirror polished finishing. In one embodiment, the preform plate 20 may have a thickness of between about 500 μm and about 1000 μm. Nonetheless, it should be understood by those of skill in the art that the present invention is not limited by the hardness of the first surface 14 or thickness of the preform plate 20. In alternative embodiments, the first surface 14 may be made of a material of the same or lesser hardness than the bonding wire 16. The thickness of the preform plate 20 may depend on, for example, the material from which the preform plate 20 is made and/or the shaping forces involved.

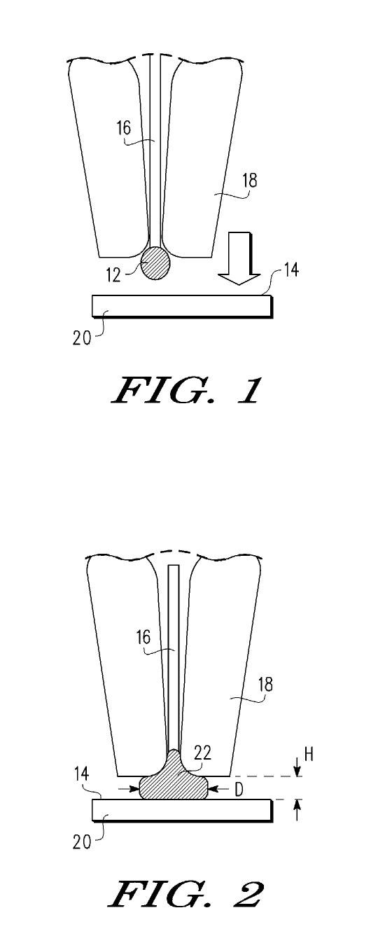

Referring now to FIG. 2, a preformed bonding ball 22 is shown. The preformed bonding ball 22 is formed by deforming the bonding ball 12 of FIG. 1 against the first surface 14, thereby mechanically preforming or preconditioning the bonding ball 12 to a substantially ball bond shape. More particularly, the preformed bonding ball 22 is formed by pressing the bonding ball 12 against the first surface 14, thus squashing the bonding ball 12 between the first surface 14 and the capillary bonding tool 18 into a substantially ball bond shape.

In one embodiment, the bonding ball 12 may be deformed to a predetermined ball bond diameter D of, for example, between about 40 μm and about 80 μm and a predetermined ball bond height H of, for example, between about 10 μm and about 30 μm. It should however be understood by those of skill in the art that the present invention is not limited by the dimensions of the preformed bonding ball 22. Rather, the dimensions of the preformed bonding ball 22 may depend on, among other things, the subsequent ball bond requirements, the wire type employed and the deformation parameters such as, for example, the impact force applied.

Although the first surface 14 is shown as being a planar surface in the embodiment shown, it should be understood that the present invention is not limited to deformation against planar surfaces. The preformed bonding ball 22 may in alternative embodiments be formed by deforming the bonding ball 12 against a nonplanar surface (see, for example, FIG. 4 described below).

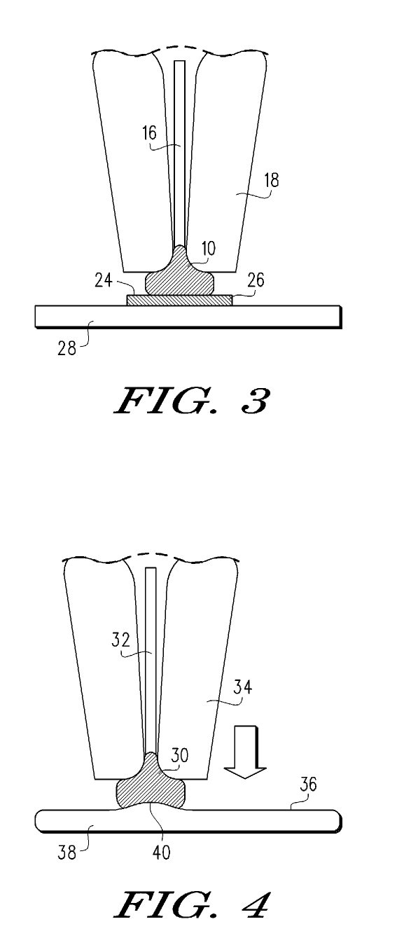

The preformed bonding ball 22 is subsequently removed from the first surface 14 by the capillary bonding tool 18 and moved to enable it to be brought into contact with a second surface or bonding site 24 as shown in FIG. 3. The second surface or bonding site 24 is remote or spaced from the first surface 14. In one embodiment, the bonding site 24 is adjacent the first surface 14.

Referring now to FIG. 3, a ball bond 10 is shown. The ball bond 10 is formed by bonding the preformed bonding ball 22 of FIG. 2 to the second surface or bonding site 24. In the embodiment shown, the bonding site 24 is a surface of a connection pad 26 of an integrated circuit (IC) die 28.

As the bonding ball 12 of FIG. 1 is at least partially, more preferably wholly, preformed to the shape of the ball bond 10, the capillary bonding tool 18 is able to bond the preformed bonding ball 22 directly to the bonding site 24 with reduced pressure, ultrasonic energy and time, as compared to conventional ball bonding processes, since pressure, ultrasonic energy and time are mainly or only required for forming a metallurgical weld between the preformed bonding ball 22 and the connection pad 26, and less or not also to flatten the bonding ball 12. In some embodiments, typical ball bonding stressors such as impact force, contact power and contact force may be substantially eliminated during the step of forming the ball bond 10 on the connection pad 26. In this manner, pressure exerted on the connection pad 26 during the bonding step is reduced and consequently reliability is improved. Further advantageously, pressure exerted on the connection pad 26 is also further reduced because the preformed bonding ball 22 disperses pressure on the connection pad 26 due to its increased diameter D. In one embodiment, the ball bond 10 is formed by applying the following parameters to an ASM Eagle 60: Standby Power=0, Search Time=0, Search Speed=82, Contact time=3, Contact Power=0, Contact Force=85, Bond Time=25, Bond Power=40 and Bond Force=21. However, it should be understood that the present invention is not limited to a particular set of bonding parameters. Rather, the optimum bonding parameters are dependent on wire type, pad metallization and device configurations.

The connection pad 26 may be of sensitive pad structure such as, for example, a bond over active (BOA) pad structure, a bond pad formed over a low-κ structure or a diamond shaped via design. In one embodiment, the connection pad 26 may have a thickness of less than 0.13 μm. The connection pad 26 may be made of aluminum (Al) or other electrically conductive material as is known in the art. It should however be understood by those of skill in the art that the present invention is not limited by the type or thickness of the connection pad 26 or the material with which the connection pad 26 is made. Rather, these would depend on the application in which the present invention is put to use.

The IC die 28 may be a processor, such as a digital signal processor (DSP), a special function circuit, such as a memory address generator, or a circuit that performs any other type of function as is known in the art and commercially available. The semiconductor device 10 is not limited to a particular technology such as CMOS, or derived from any particular wafer technology.

Once the ball bond 10 is formed, the bonding wire 16 is either cut to form a stud bump (not shown), or run to a corresponding bonding site (not shown) on a lead frame or substrate and bonded thereto.

The process described above with reference to FIGS. 1 through 3 is repeated for subsequent bonds.

Referring now to FIG. 4, a preformed bonding ball 30 in accordance with another embodiment of the present invention is shown. The preformed bonding ball 30 is formed by bringing a bonding ball (not shown) formed at an end of a bonding wire 32 near the tip of a capillary bonding tool 34 towards a first surface 36, as indicated by the arrow in FIG. 4, and deforming the bonding ball against the first surface 36. In the embodiment shown, the first surface 36 is a surface of a preform plate 38 having a protrusion 40 formed thereon.

Since the elements of the bonding ball, the bonding wire 32 and the capillary bonding tool 34 in the present embodiment are the same as in the previous embodiment, further detailed description of these elements is not required for a complete understanding of the present invention and will therefore be omitted.

In the embodiment shown, the bonding ball is brought down directly onto the protrusion 40 and is consequently deformed according to the contour of the first surface 36.

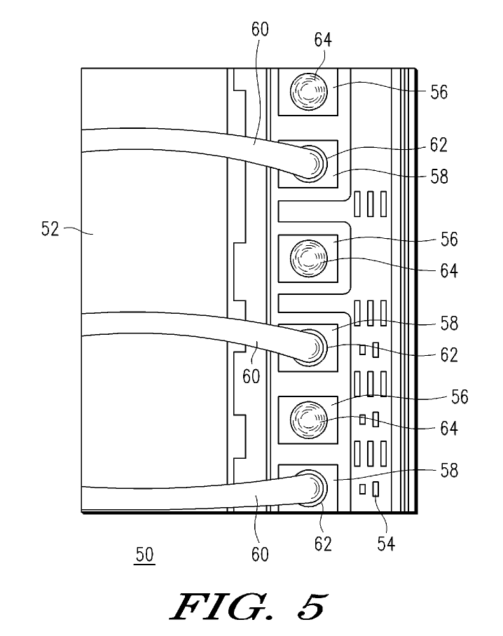

Referring now to FIG. 5, an enlarged partial top plan view of a semiconductor package 50 is shown. The semiconductor package 50 includes a die carrier 52 having a plurality of bonding sites (not shown). An integrated circuit (IC) die 54 is attached to the die carrier 52. The IC die 54 includes a plurality of first connection pads 56 and a plurality of second connection pads 58. A plurality of wire bonds 60 electrically connect the bonding sites on the die carrier 52 to the second connection pads 58 on the IC die 54. Each of the wire bonds 60 includes a ball bond 62 formed on respective ones of the second connection pads 58 on the IC die 52. The ball bonds 62 are formed using the method described above, for example, with reference to FIGS. 1 through 3, except that preformed bonding balls are first deformed (shaped) using the first connection pads 56 by pressing an FAB against the first connection pads 56 on the IC die 54. Subsequently preformed ball bonds are bonded to the second connection pads 58 on the IC die 54.

In one embodiment of the invention, the first connection pads 56 have indentation marks 64 that are formed when the FAB is pressed against a surface thereof, which forms an indentation in the first connection pads 56. The indentation marks 64 have a diameter that is substantially the same as a diameter of the preformed ball bonds and a depth of between about 100 nanometers (nm) to 700 nm depending on, amongst other things, the type of wire used and the wire bonder employed.

The die carrier 52 may be a substrate or a lead frame. Accordingly, the bonding sites on the die carrier 52 may be pad surfaces of a substrate or lead frame fingers. As substrates, lead frames and their respective bonding sites are known to those of ordinary skill in the art, detailed descriptions thereof are not necessary for a full understanding of the invention.

The IC die 54 may be as described above with reference to FIG. 3.

In the embodiment shown, the bonding balls are preformed so that they have substantially the shape as the ball bond 62. Consequently, the indentation marks 64 on the first connection pads 56 are of a substantially same shape as the corresponding surfaces of the ball bonds 62 in contact with the second connection pads 58. The similarity in shape suggests that substantially reduced stresses or no further stresses are exerted on the second connection pads 58 by the capillary bonding tool during the ball bonding step.

Although ball bonds are described in the above embodiments as being formed on connection pads of an IC die, those of ordinary skill in the art will understand that the present invention is not limited to ball bond formation on IC dice. In alternative embodiments, the ball bonds may be formed, for example, on the connection pads of a substrate.

As is evident from the foregoing discussion, the present invention provides a method of forming a ball bond that requires less pressure exertion on a bonding site during the ball bonding step because the bonding ball is preformed to substantially the shape of a ball bond before bonding to the bonding site. Thus, pressure exerted on the bonding site during the ball bonding step is largely for forming a metallurgical weld between the preformed bonding ball and the bonding site, and less or not also for flattening the bonding ball. Consequently, pressure exerted on the bonding site during the ball bonding step can be reduced and wire bonding integrity is thus enhanced. Advantageously, the present invention can be applied to sensitive bond pad applications such as, for example, Bond Over Active (BOA) circuitry, Low-κ structures, bond pads with a thickness of less than 0.13 μm, Diamond shaped Via designs, etc.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A semiconductor package, comprising:
a die carrier having a plurality of bonding sites;
an integrated circuit (IC) die attached to the die carrier, the IC die having a plurality of first connection pads and a plurality of second connection pads; and
a plurality of wires electrically connecting the bonding sites on the die carrier to the second connection pads on the IC die, wherein the wires include bonding balls that are pressed against the first connection pads prior to being connected to the second connection pads.

2. The semiconductor package of claim 1, wherein pressing the bond balls against the first connection pads forms pre-formed ball bonds prior to connection of the wires to the second connection pads.

3. The semiconductor package of claim 2, wherein indentation marks are formed on the first connection pads.

4. The semiconductor package of claim 3, wherein the indentation marks on the first connection pads have substantially the same shape as corresponding surfaces of the pre-formed ball bonds in contact with the second connection pads.

5. The semiconductor package of claim 1, wherein the first connection pads have a harder surface than the bonding wires.

6. The semiconductor package of claim 1, wherein the bonding ball is deformed to a diameter of between about 40 microns (μm) and about 80 μm.

7. The semiconductor package of claim 1, wherein the bonding ball is deformed to a predetermined ball bond height.

8. The semiconductor package of claim 7, wherein the bonding ball is deformed to a height of between about 10 μm and about 30 μm.
